(19) United States
(12) Patent Application Publication
(10) Pub. No.: US 2012/0306561 A1
(43) Pub. Date: Dec. 6, 2012

(54) I/O CIRCUIT AND INTEGRATED CIRCUIT

(75) Inventors: Wei CAO, Shanghai (CN); Fangming DAI, Shanghai (CN)

(73) Assignee: HUAWEI TECHNOLOGIES CO., LTD., Shenzhen (CN)

(21) Appl. No.: 13/483,877

(22) Filed: May 30, 2012

Related U.S. Application Data
(63) Continuation of application No. PCT/CN2011/074882, filed on May 30, 2011.

(51) Int. Cl. H03K 17/687

(52) U.S. Cl. 327/434

(57) ABSTRACT

An I/O circuit includes: a boost module, a P path, an N path, a PMOS driving transistor, and an NMOS driving transistor, where: a rising edge of an output signal of a non-inverting port of the boost module is slower than a falling edge; a grid electrode of the PMOS driving transistor is connected to the non-inverting port of the boost module via the P path and a grid electrode of the NMOS driving transistor is connected to an inverting port of the boost module via the N path; and the P path includes an odd number of inverters connected in series and the N path includes an even number of inverters connected in series. The present invention also provides an integrated circuit.

### CROSS-REFERENCE TO RELATED APPLICATIONS

This application is a continuation of International Application No. PCT/CN2011/074882, filed on May 30, 2011, which is hereby incorporated by reference in its entirety.

### FIELD OF THE INVENTION

The present invention relates to the field of electronic technologies, and in particular, to an I/O circuit and an integrated circuit.

### BACKGROUND OF THE INVENTION

An I/O (Input and Output) circuit is indispensable to a chip and provides functions such as signal transmission, power supply, and ESD (Electro-Static discharge, electro-static discharge) protection in the entire chip. Because functions of a chip are increasingly complicated and a scale of the chip is continuously larger, required power consumption is increasingly higher, and therefore requirements on performance, power consumption, and a size of the I/O circuit of the chip are also increasingly higher.

FIG. 1 is a structural diagram of an I/O circuit in the prior art. As shown in FIG. 1, in an existing I/O circuit, control signals Net P and Net N that control a PMOS (Positive Channel Metal Oxide Semiconductor) driving transistor and an NMOS (Negative Channel Metal Oxide Semiconductor) driving transistor come from the same port of a boost module (an inverting port ON in FIG. 1). The control signals Net P and Net N control the PMOS driving transistor and the NMOS driving transistor respectively through two structurally symmetric paths. An envelope relationship between the control signals Net P and Net N of the I/O circuit shown in FIG. 1 may be that shown in FIG. 2 or FIG. 3.

As shown in FIG. 2 and FIG. 3, in the prior art, the control signals Net P and Net N come from the same port of the boost module and control the PMOS driving transistor and the NMOS driving transistor respectively through two structurally symmetric paths, so that the control signals Net P and Net N are basically coincident (as shown in FIG. 2) or even in an incorrect envelope relationship (Net N envelopes Net P as shown in FIG. 3).

The incorrect envelope relationship between the control signals Net P and Net N generated by the existing I/O circuit has a great impact on Delay Time (delay time) and Transition Time (transition time, the time taken for transition from a high level to a low level or from a low level to a high level) of a final output signal, and further has an impact on quality of the output signal; and even worse, because the PMOS and NMOS, as the driving transistors of the I/O circuit, have a large size, the control signals Net P and Net N cause a significantly strong leakage current between a Power (power supply) and a Ground (ground) in a transition process and further imposes a potential threat on reliability of the entire chip.

In the prior art, even though the size of the boost module and the size of inverters on the two paths are manually adjusted to realize a relationship that Net P envelopes Net N, because this method must consider a compromise relationship among factors such as the envelope relationship, the Delay Time and Transition Time of the final output signal, a working frequency of the I/O circuit, and whether the driving transistors of the I/O circuit are able to be normally driven, the implementation is complicated and the realized envelope relationship is non-obvious.

### SUMMARY OF THE INVENTION

In view of this, the purpose of the present invention is to provide an I/O circuit and an integrated circuit, which are capable of generating an obvious relationship that a PMOS driving transistor control signal envelopes an NMOS driving transistor control signal.

An embodiment of the present invention provides an I/O circuit, including: a boost module, a P path, an N path, a PMOS driving transistor, and an NMOS driving transistor, where:

a rising edge of an output signal of a non-inverting port of the boost module is slower than a falling edge;

a grid electrode of the PMOS driving transistor is connected to the non-inverting port of the boost module via the P path and a grid electrode of the NMOS driving transistor is connected to an inverting port of the boost module via the N path; and

the P path includes an odd number of inverters connected in series and the N path includes an even number of inverters connected in series.

An embodiment of the present invention further provides an integrated circuit, which includes the I/O circuit.

An embodiment of the present invention further provides an I/O circuit, including: a boost module, a P path, an N path, a PMOS driving transistor, and an NMOS driving transistor, where:

a falling edge of an output signal of a non-inverting port of the boost module is slower than a rising edge;

a grid electrode of the PMOS driving transistor is connected to an inverting port of the boost module via the P path and a grid electrode of the NMOS driving transistor is connected to a non-inverting port of the boost module via the N path; and

the P path includes an even number of inverters connected in series and the N path includes an odd number of inverters connected in series.

An embodiment of the present invention further provides an integrated circuit, which includes the I/O circuit.

According to specific embodiments of the present invention, the present invention discloses the following technical benefits:

In the I/O circuit in the embodiments of the present invention, based on a waveform feature of the output signal of the non-inverting port of the boost module, the grid electrode of the PMOS driving transistor and the grid electrode of the NMOS driving transistor are designed to connect to different phase ports of the boost module respectively via the P path and the N path, so that the control signal Net P controlling the PMOS driving transistor and the control signal Net N controlling the NMOS driving transistor come from the non-inverting port and the inverting port of the boost module respectively; furthermore, the number of inverters on the P path and that on the N path are designed to be odd and even differently; thereby, the I/O circuit in the embodiments of the present invention is capable of generating an obvious relationship that the control signal Net P of the PMOS driving transistor envelopes the control signal Net N of the NMOS driving transistor.

### BRIEF DESCRIPTION OF THE DRAWINGS

FIG. 1 is a structural diagram of an I/O circuit in the prior art;

FIG. 2 is a diagram of a first envelope relationship between the control signals Net P and Net N of the I/O circuit shown in FIG. 1;

FIG. 3 is a diagram of a second envelope relationship between the control signals Net P and Net N of the I/O circuit shown in FIG. 1;

FIG. 4 is a structural diagram of an I/O circuit according to a first embodiment of the present invention;

FIG. 5 is a circuit structural diagram of a boost module according to an embodiment of the present invention;

FIG. 6 is a waveform diagram of an input signal received by a boost module and an output signal of a non-inverting port according to an embodiment of the present invention;

FIG. 7 is a waveform diagram of signals output by a non-inverting port and an inverting port of a boost module respectively according to an embodiment of the present invention;

FIG. 8 is a diagram of an envelope relationship between control signals Net P and Net N of an I/O circuit according to an embodiment of the present invention;

FIG. 9 is a structural diagram of an I/O circuit according to a second embodiment of the present invention;

FIG. 10 is a structural diagram of an I/O circuit according to a third embodiment of the present invention; and

FIG. 11 is a structural diagram of an I/O circuit according to a fourth embodiment of the present invention.

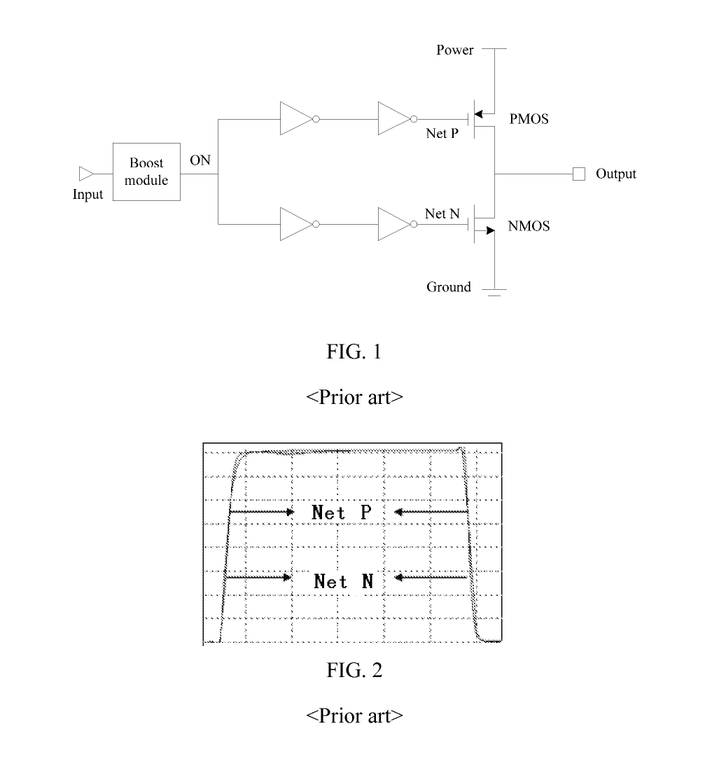

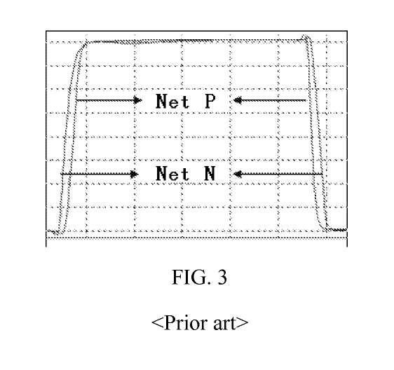

### DETAILED DESCRIPTION OF THE EMBODIMENTS

To better explain the purpose, features, and merits of the present invention, the present invention is described in detail below with reference to the accompanying drawings and specific embodiments.

In view of this, the purpose of the present invention is to provide an I/O circuit and an integrated circuit, which are capable of generating an obvious relationship that a PMOS driving transistor control signal envelopes an NMOS driving transistor control signal.

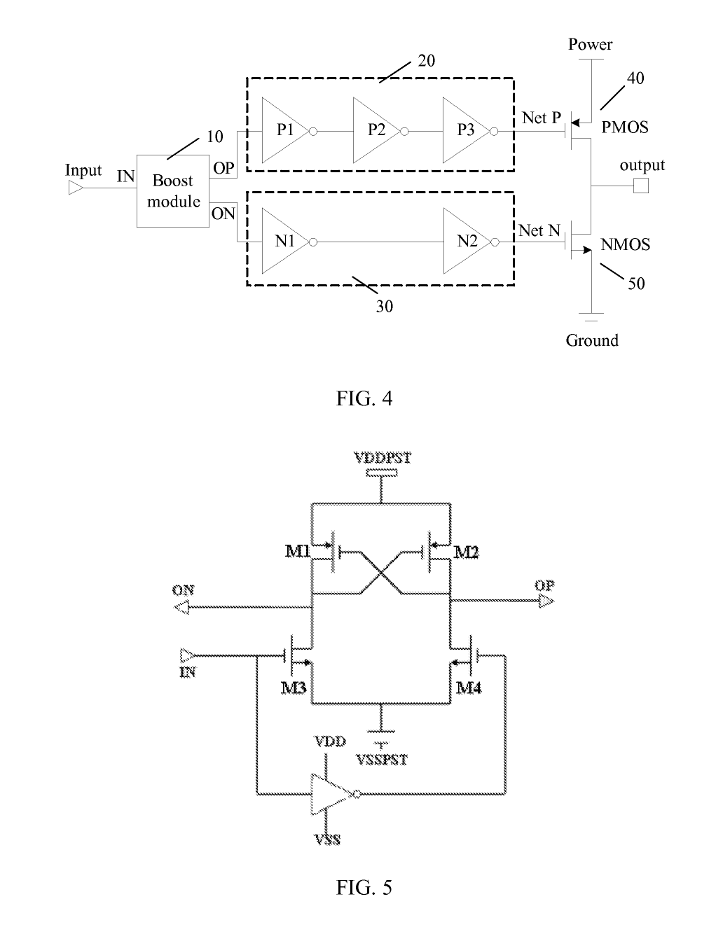

FIG. 4 is a structural diagram of an I/O circuit according to a first embodiment of the present invention. As shown in FIG. 4, the I/O circuit includes a boost module 10, a P path 20, an N path 30, a PMOS driving transistor 40, and an NMOS driving transistor 50.

An input port IN of the boost module 10 is an input end Input of the I/O circuit; a non-inverting port OP of the boost module 10 is connected to a grid electrode of the PMOS driving transistor 40 via the P path 20; and an inverting port ON of the boost module 10 is connected to a grid electrode of the NMOS driving transistor 50 via the N path 30.

A source electrode of the PMOS driving transistor 40 is connected to a working power supply Power; a source electrode of the NMOS driving transistor 50 is connected to a ground (Ground); a drain electrode of the PMOS driving transistor 40 and a drain electrode of the NMOS driving transistor 50 are short-circuited to function as an output end (Output) of the I/O circuit.

In this embodiment of the present invention, the P path 20 includes an odd number of inverters that are connected in series to form a series branch circuit. Specifically, in the series branch circuit, an output end of a previous inverter is connected to an input end of a next inverter; an input end of the first inverter is connected to the non-inverting port OP of the boost module 10; and an output end of the last inverter is connected to the grid electrode of the PMOS driving transistor 40.

The N path 30 includes an even number of inverters that are also connected in series to form a series branch circuit. Specifically, in the series branch circuit, an output end of a previous inverter is connected to an input end of a next inverter; an input end of the first inverter is connected to the inverting port ON of the boost module 10; and an output end of the last inverter is connected to the grid electrode of the NMOS driving transistor 50.

It should be noted that, in the I/O circuit in the first embodiment of the present invention, the boost module 10 has the following waveform feature: A rising edge of an output signal of the non-inverting port of the boost module 10 is slower than a falling edge.

In this embodiment of the present invention, based on the waveform feature of the boost module 10, the grid electrode of the PMOS driving transistor 40 and the grid electrode of the NMOS driving transistor 50 are designed to connect to the non-inverting port OP and inverting port ON of the boost module 10 respectively via the P path 20 and the N path 30, so that the control signal Net P controlling the PMOS driving transistor 40 and the control signal Net N controlling the NMOS driving transistor 50 come from the non-inverting port and the inverting port of the boost module 10 respectively; furthermore, the number of inverters on the P path 20 and that on the N path 30 are designed to be odd and even differently; thereby, the I/O circuit in this embodiment of the present invention is capable of generating an obvious relationship that the control signal Net P of the PMOS driving transistor 40 envelopes the control signal Net N of the NMOS driving transistor 50.

As shown in FIG. 4, this embodiment of the present invention is described by taking that the P path 20 includes three inverters and the N path 30 includes two inverters as an example.

As shown in FIG. 4, the P path 20 includes a first inverter P1, a second inverter P2, and a third inverter P3; and the N path 30 includes a fourth inverter N1 and a fifth inverter N2.

An input end of the first inverter P1 is connected to the non-inverting port OP of the boost module 10 and an output end of the first inverter P1 is connected to an input end of the second inverter P2; an output end of the second inverter P2 is connected to an input end of the third inverter P3; and an output end of the third inverter P3 is connected to the grid electrode of the PMOS driving transistor 40.

An input end of the fourth inverter N1 is connected to the inverting port ON of the boost module 10 and an output end of the fourth inverter N1 is connected to an input end of the fifth inverter N2; and an output end of the fifth inverter N2 is connected to the grid electrode of the NMOS driving transistor 50.

In a practical application, it is only necessary to ensure that the P path 20 includes an odd number of inverters and that the N path 30 includes an even number of inverters. The specific number of inverters included in the two paths may be set according to a need of the practical application.

In a practical design, due to a restriction of the area of the I/O circuit, selection of the boost module 10 in the I/O circuit is based on a principle that the area is as small as possible and that a structure is as simple as possible on the premise that a function is ensured. FIG. 5 is a schematic structural diagram of a common boost module.

FIG. 5 is a circuit structural diagram of a boost module according to an embodiment of the present invention. As shown in FIG. 5, the boost module 10 includes a first PMOS transistor M1, a second PMOS transistor M2, a first NMOS transistor M3, a second NMOS transistor M4, and a sixth inverter T1.

A source electrode of the first PMOS transistor M1 and a source electrode of the second PMOS transistor M2 are short-circuited and connected to a high-voltage power supply VDDPST (for example, 3.3 V) together.

A drain electrode of the first PMOS transistor M1 and a grid electrode of the second PMOS transistor M2 are short-circuited to function as an inverting port ON of the boost module 10.

A drain electrode of the second PMOS transistor M2 and a grid electrode of the first PMOS transistor M1 are short-circuited to function as the non-inverting port OP of the boost module 10.

A drain electrode of the first NMOS transistor M3 is connected to the inverting port ON of the boost module; and a drain electrode of the second NMOS transistor M4 is connected to the non-inverting port OP of the boost module 10.

A source electrode of the first NMOS transistor M3 and a source electrode of the second NMOS transistor M4 are short-circuited and connected to a ground VSSPST together.

A grid electrode of the first NMOS transistor M3 is connected to an input end of the sixth inverter T1 and an output end of the sixth inverter T1 is connected to a grid electrode of the second NMOS transistor M4.

A power port of the sixth inverter T1 is connected to a low-voltage power supply VDD (for example, 1.1 V) and a ground VSS.

The grid electrode of the first NMOS transistor M3 and a public end of the sixth inverter T1 are connected to function as an input port of the boost module 10.

With reference to FIG. 5, the non-inverting port OP and the inverting port ON of the boost module 10 are both based on the input port IN. That is, the non-inverting port OP of the boost module 10 is configured to output a signal that has the same phase as an input signal received at the input port IN while the inverting port ON is configured to output a signal that has a phase inverted from the input signal received at the input port IN.

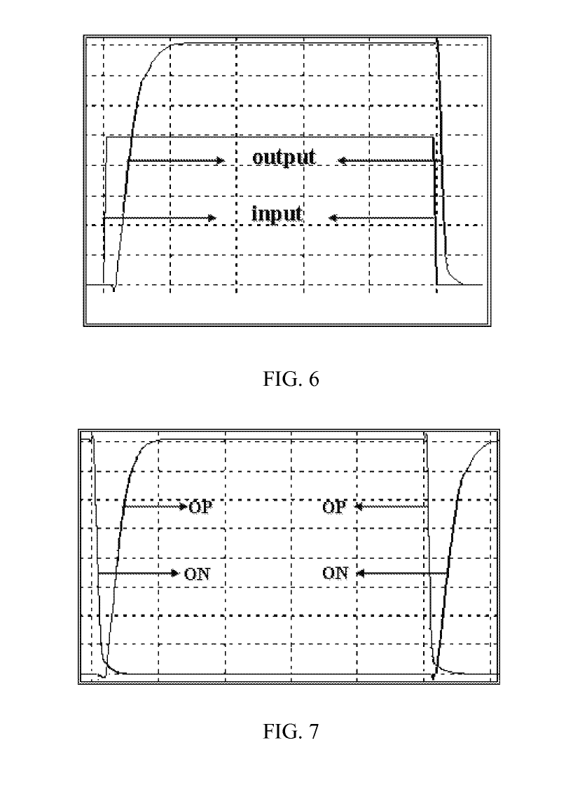

FIG. 6 is a waveform diagram of an input signal received by the boost module 10 and an output signal of the non-inverting port according to the first embodiment of the present invention. For the boost module 10 shown in FIG. 5, in order to avoid occurrence of a step on a falling edge of the output signal, which further affect signal quality, the size of the first NMOS transistor M3 and the second NMOS transistor M4 may be designed to be larger than that of the first PMOS transistor M1 and the second PMOS transistor M2. For example, the size of the first NMOS transistor M3 and the second NMOS transistor M4 may be designed to be approximately 10 times that of the first PMOS transistor M1 and the second PMOS transistor M2. In this way, the output signal of the non-inverting port OP of the boost module 10 has the following feature: A rising edge of the output signal is slower than the falling edge. That is, as shown in FIG. 6, the rising time for the output signal to rise from a low level to a high level is obviously longer than the falling time for the signal to fall from a high level to a low level. An x-coordinate of the waveform shown in FIG. 6 represents time and a y-coordinate of the waveform represents voltage. The input shown in FIG. 6 is the input signal received by the boost module 10.

Then, waveforms of the signals output by the non-inverting port OP and the inverting port ON of the boost module respectively are as shown in FIG. 7. The signals output by the two ports respectively are phase-inverted.

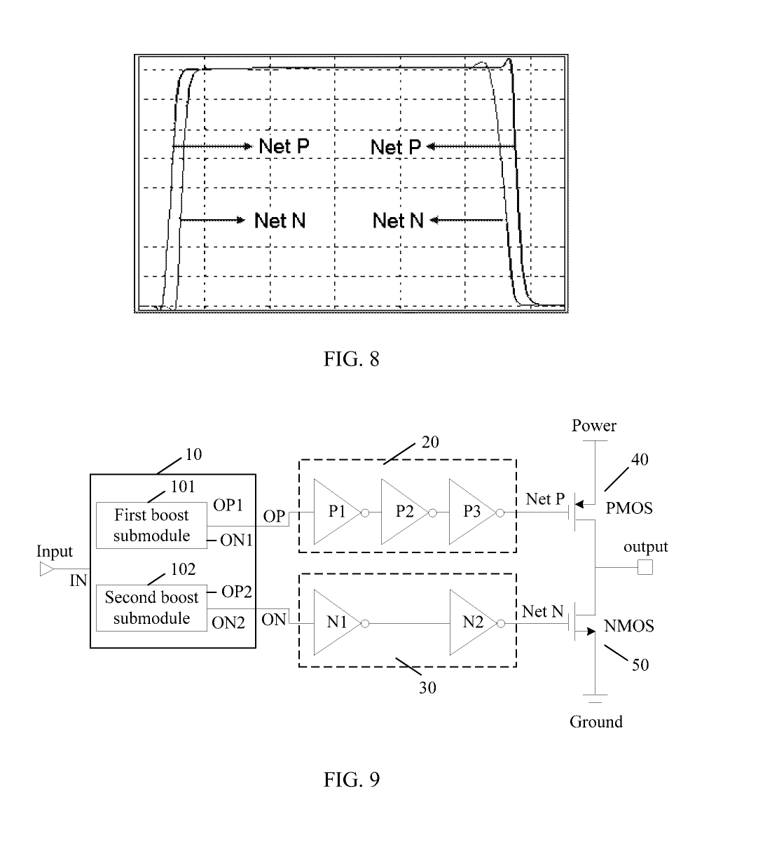

In this embodiment of the present invention, a signal of the P path 20 is taken from the non-inverting port OP of the boost module 10 and controls the grid electrode of the PMOS driving transistor 40 through an odd number (such as three) of inverters; a signal of the N path 30 is taken from the inverting port ON of the boost module 10 and controls the grid electrode of the NMOS driving transistor 50 through an even number (such as two) of inverters. With reference to features of the input signal received by the boost module 10 and the signals output by the two ports of the boost module 10 respectively, an envelope relationship between the control signal Net P of the PMOS driving transistor 40 and the control signal Net N of the NMOS driving transistor 50 may be obtained, as shown in FIG. 8.

An analysis with reference to FIG. 6 and FIG. 7 is as follows: As shown in FIG. 7, after being boosted by the boost module 10, the input signal is output by the non-inverting port OP and the inverting port ON respectively, where a rising edge of a waveform output by the OP port is slower than a falling edge of an output signal of the ON port and a rising edge of the output signal of the ON port is slower than a falling edge of an output signal of the OP port. Therefore, after the output signal of the OP port goes through the odd number (such as three) of inverters in the P path 20 and the output signal of the ON port goes through the even number (such as two) of inverters in the N path 30, an obvious form that Net P envelopes Net N as shown in FIG. 8 is generated, which is a correct envelope relationship and meets a requirement of the I/O circuit.

The I/O circuit in this embodiment of the present invention, based on a conventional I/O circuit structure, takes into account the waveform feature of the boost module 10 and through the design of two paths, generates an obvious relationship that the control signal Net P of the PMOS driving transistor 40 envelopes the control signal Net N of the NMOS driving transistor 50, where a degree of the enveloping is tunable by adjusting the size of the boost module 10 and the size of the inverters included in the two paths. The I/O circuit truly implements the tuning of the envelope relationship according to an actual need without a need to consider a compromise relationship among factors such as the envelope relationship, the Delay Time and Transition Time of the final output signal, a working frequency of the I/O circuit, and whether the driving transistors in the I/O circuit are able to be normally driven.

The I/O circuit in this embodiment of the present invention effectively reduces leakage current between the power supply and the ground in a signal transition process and has a merit of easily adjusting the Delay Time and Transition Time of the final output signal, thereby ensuring quality of the final output signal and meeting a requirement on high-quality transmission of a signal by the entire chip.

In the first embodiment of the present invention, the P path and the N path are connected to the non-inverting port and the inverting port of the same boost module respectively. In another embodiment of the present invention, the P path and the N path may be connected to the non-inverting port and the inverting port of different boost modules respectively, provided that the following is ensured: The different boost modules receive the same input signal, the grid electrode of the PMOS driving transistor is connected to the non-inverting port of one of the boost modules via an odd number of inverters, and the grid electrode of the NMOS driving transistor is connected to the inverting port of one of the boost modules via an even number of inverters.

FIG. 9 is a structural diagram of an I/O circuit according to a second embodiment of the present invention. As shown in FIG. 9, the circuit in the second embodiment is different from the circuit in the first embodiment in that: the boost module 10 of the I/O circuit includes two boost submodules, a first boost submodule 101 and a second boost submodule 102, and input ends of the two boost submodules are short-circuited and then connected to an input signal together.

A non-inverting port OP1 of the first boost submodule 101 functions as the non-inverting port OP of the boost module 10 and is connected to the input end of the P path 20.

An inverting port ON2 of the second boost submodule 102 functions as the inverting port ON of the boost module 10 and is connected to the output end of the N path 30.

The rest of the circuit in the second embodiment is the same as that in the first embodiment and is not described here.

A structure, a function, and a working principle of each of the boost submodules are the same as those of the boost module in the first embodiment.

It should be noted that, in this embodiment of the present invention, the boost module may further include several (without being limited to two) boost submodules, provided that input ports of the boost submodules are short-circuited and connected to the same input signal. In this case, a non-inverting port of any one of the several boost submodules may be defined as the non-inverting port of the boost module and connected to the input end of the P path and an inverting port of any one of the boost submodules may be defined as the inverting port of the boost module and connected to the input end of the N path.

Corresponding to the I/O circuit provided in the first and the second embodiments of the present invention, an embodiment of the present invention further provides an integrated circuit, where the integrated circuit may include the I/O circuit described in the first and the second embodiments. The integrated circuit may be any CMOS (Complementary Metal Oxide Semiconductor, complementary metal oxide semiconductor) integrated circuit that is capable of generating two paths of signals that have an envelope relationship.

The I/O circuit in the first and the second embodiments of the present invention, when the rising edge of the output signal of the non-inverting port of the boost module 10 is slower than the falling edge, is capable of realizing an obvious relationship that the control signal of the PMOS driving transistor envelopes the control signal of the NMOS driving transistor. When the output signal of the non-inverting port of the boost module presents a feature that the falling edge is slower than the rising edge, a third embodiment of the present invention provides an I/O circuit structure that is also capable of realizing the relationship that the control signal of the PMOS driving transistor envelopes the control signal of the NMOS driving transistor.

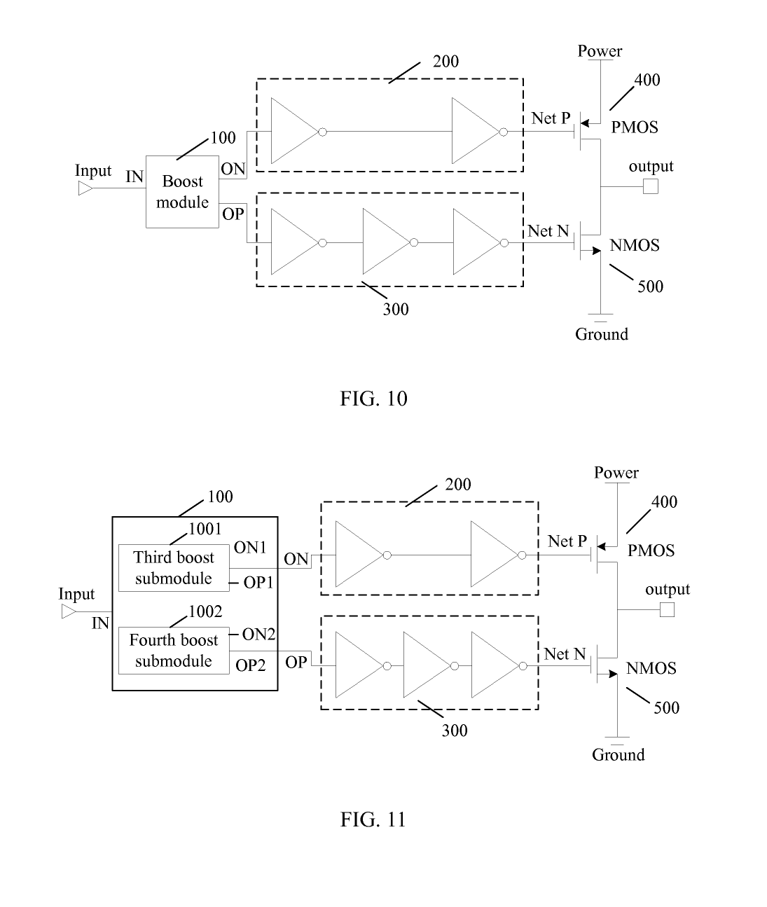

FIG. 10 is a structural diagram of an I/O circuit according to a third embodiment of the present invention. As shown in FIG. 10, the I/O circuit includes a boost module 100, a P path 200, an N path 300, a PMOS driving transistor 400, and an NMOS driving transistor 500.

An input port IN of the boost module 100 is an input end Input of the I/O circuit; an inverting port ON of the boost module 100 is connected to a grid electrode of the PMOS driving transistor 400 via the P path 200; and a non-inverting port OP of the boost module 100 is connected to a grid electrode of the NMOS driving transistor 500 via the N path 300.

A source electrode of the PMOS driving transistor 400 is connected to a working power supply Power; a source electrode of the NMOS driving transistor 500 is connected to a ground Ground; a drain electrode of the PMOS driving transistor 400 and a drain electrode of the NMOS driving transistor 500 are short-circuited to function as an output end Output of the I/O circuit.

In this embodiment of the present invention, the P path 200 includes an even number of inverters that are connected in series to form a series branch circuit. Specifically, in the series branch circuit, an output end of a previous inverter is connected to an input end of a next inverter; an input end of the first inverter is connected to the inverting port ON of the boost module 100; and an output end of the last inverter is connected to the grid electrode of the PMOS driving transistor 400.

The N path 300 includes an odd number of inverters that are connected in series to form a series branch circuit. Specifically, in the series branch circuit, an output end of a previous inverter is connected to an input end of a next inverter; an input end of the first inverter is connected to the non-inverting port OP of the boost module 100; and an output end of the last inverter is connected to the grid electrode of the NMOS driving transistor 500.

It should be noted that, in the I/O circuit in the third embodiment of the present invention, the boost module 100 has the following waveform feature: A falling edge of an output signal of the non-inverting port of the boost module 100 is slower than a rising edge.

In this embodiment of the present invention, based on the waveform feature of the boost module 100, the grid electrode of the PMOS driving transistor 400 and the grid electrode of the NMOS driving transistor 500 are designed to connect to the inverting port ON and non-inverting port OP of the boost module 100 respectively via the P path 200 and the N path 300, so that a control signal Net P controlling the PMOS driving transistor 400 and a control signal Net N controlling the NMOS driving transistor 500 come from the non-inverting port and the inverting port of the boost module 100 respectively; meanwhile, the number of inverters on the P path 200 and that on the N path 300 are designed to be odd and even differently; thereby, the I/O circuit in the embodiment of the present invention is capable of generating an obvious relationship that the control signal Net P of the PMOS driving transistor 400 envelopes the control signal Net N of the NMOS driving transistor 500.

In FIG. 10, that the P path 200 includes two inverters and the N path 300 includes three inverters is taken as an example for description. In a practical application, it is only necessary to ensure that the P path 200 includes an even number of inverters and that the N path 300 includes an odd number of inverters. The specific number of inverters included in the two paths may be set according to a need of the practical application.

A working principle of the I/O circuit in the third embodiment shown in FIG. 10 is similar to that in the first embodiment and is not described here.

Accordingly, in the third embodiment of the present invention, the P path and the N path are connected to the inverting port and the non-inverting port of the same boost module respectively. In another embodiment of the present invention, the P path and the N path may be connected to the inverting port and the non-inverting port of different boost modules respectively, provided that the following is ensured: The different boost modules receive the same input signal, the grid electrode of the PMOS driving transistor is connected to an inverting port of one of the boost modules via an even number of inverters, and the grid electrode of the NMOS driving transistor is connected to a non-inverting port of one of the boost modules via an odd number of inverters.

FIG. 11 is a structural diagram of an I/O circuit according to a fourth embodiment of the present invention. As shown in FIG. 11, the circuit in the fourth embodiment is different from the circuit in the third embodiment in that: the boost module 100 of the I/O circuit includes two boost submodules, a third boost submodule 1001 and a fourth boost submodule 1002, and input ends of the two boost submodules are short-circuited and connected to an input signal together.

An inverting port ON1 of the third boost submodule 1001 functions as an inverting port ON of the boost module 100 and is connected to an input end of the P path 200.

A non-inverting port OP2 of the fourth boost submodule 1002 functions as a non-inverting port OP of the boost module 100 and is connected to an input end of the N path 300.

The rest of the circuit in the fourth embodiment is the same as that in the third embodiment and is not described here.

A structure, a function, and a working principle of each of the boost submodules are the same as those of the boost module in the third embodiment.

It should be noted that, in this embodiment of the present invention, the boost module may further include several (without being limited to two) boost submodules, provided that input ports of the boost submodules are short-circuited and connected to the same input signal. In this case, a non-inverting port of any one of the several boost submodules may be defined as the non-inverting port of the boost module and connected to the input end of the N path and an inverting port of any one of the boost submodules may be defined as the inverting port of the boost module and connected to the input end of the P path.

Corresponding to the I/O circuit provided in the third and the fourth embodiments of the present invention, an embodiment of the present invention provides an integrated circuit, where the integrated circuit may include the I/O circuit in the third and the fourth embodiments. The integrated circuit may be any CMOS (Complementary Metal Oxide Semiconductor, complementary metal oxide semiconductor) integrated circuit that is capable of generating two paths of signals that have an envelope relationship.

Detailed in the foregoing are the I/O circuit and the integrated circuit provided in the embodiments of the present invention. Although the principles and implementation manners of the present invention are described with reference to exemplary embodiments, the embodiments are only intended to help understand the methods and core idea of the present invention. In addition, with respect to the implementation and applicability of the present invention, modifications and variations may be made by persons of ordinary skill in the art according to the idea of the present invention. Therefore, the specification shall not be construed as a limitation on the present invention.

1. An input/output (I/O) circuit, comprising a boost module, a P path, an N path, a PMOS (Positive Channel Metal Oxide Semiconductor) driving transistor, and an NMOS (Negative Channel Metal Oxide Semiconductor) driving transistor, wherein:
a rising edge of an output signal of a non-inverting port of the boost module is slower than a falling edge;
a grid electrode of the PMOS driving transistor is connected to the non-inverting port of the boost module via the P path and a grid electrode of the NMOS driving transistor is connected to an inverting port of the boost module via the N path; and
the P path comprises an odd number of inverters connected in series and the N path comprises an even number of inverters connected in series.

2. The I/O circuit according to claim 1, wherein the boost module comprises: a first PMOS transistor, a second PMOS transistor, a first NMOS transistor, a second NMOS transistor, and an inverter, wherein:
a source electrode of the first PMOS transistor and a source electrode of the second PMOS transistor are short-circuited and connected to a high-voltage power supply together;
a drain electrode of the first PMOS transistor and a grid electrode of the second PMOS transistor are short-circuited to function as the inverting port of the boost module;
a drain electrode of the second PMOS transistor and a grid electrode of the first PMOS transistor are short-circuited to function as the non-inverting port of the boost module;
a drain electrode of the first NMOS transistor is connected to the inverting port of the boost module and a drain electrode of the second NMOS transistor is connected to the non-inverting port of the boost module;
a source electrode of the first NMOS transistor and a source electrode of the second NMOS transistor are short-circuited and connected to a ground together;
a grid electrode of the first NMOS transistor is connected to an input end of the inverter and an output end of the inverter is connected to a grid electrode of the second NMOS transistor; and
the grid electrode of the first NMOS transistor and a public end of the inverter are connected to function as an input port of the boost module.

3. The I/O circuit according to claim 2, wherein the first NMOS transistor and the second NMOS transistor are larger than the first PMOS transistor and the second PMOS transistor in size.

4. The I/O circuit according to claim 1, wherein the boost module comprises several boost submodules, wherein:
input ports of the several boost submodules are short-circuited;
a non-inverting port of any one of the boost submodules functions as the non-inverting port of the boost module; and
an inverting port of any one of the boost submodules functions as the inverting port of the boost module.

5. The I/O circuit according to claim 1, wherein, in the odd number of inverters comprised by the P path, an output end of a previous inverter is connected to an input end of a next inverter, an input end of a first inverter is connected to the non-inverting port of the boost module, and an output end of a last inverter is connected to the grid electrode of the PMOS driving transistor.

6. The I/O circuit according to claim 1, wherein, in the even number of inverters comprised by the N path, an output end of a previous inverter is connected to an input end of a next inverter, an input end of a first inverter is connected to the inverting port of the boost module, and an output end of a last inverter is connected to the grid electrode of the NMOS driving transistor.

7. (canceled)

8. An input/output (I/O) circuit, comprising a boost module, a P path, an N path, a PMOS (Positive Channel Metal Oxide Semiconductor) driving transistor, and an NMOS (Negative Channel Metal Oxide Semiconductor) driving transistor, wherein:
a falling edge of an output signal of a non-inverting port of the boost module is slower than a rising edge;
a grid electrode of the PMOS driving transistor is connected to an inverting port of the boost module via the P path and a grid electrode of the NMOS driving transistor is connected to the non-inverting port of the boost module via the N path; and
the P path comprises an even number of inverters connected in series and the N path comprises an odd number of inverters connected in series.

9. The I/O circuit according to claim 8, wherein the boost module comprises multiple boost submodules, wherein:
input ports of the boost submodules are short-circuited;
a non-inverting port of any one of the boost submodules functions as the non-inverting port of the boost module; and
an inverting port of any one of the boost submodules functions as the inverting port of the boost module.

10. The I/O circuit according to claim 8, wherein, in the even number of inverters comprised by the P path, an output end of a previous inverter is connected to an input end of a next inverter, an input end of a first inverter is connected to the inverting port of the boost module, and an output end of a last inverter is connected to the grid electrode of the PMOS driving transistor.

11. The I/O circuit according to claim 8, wherein, in the odd number of inverters comprised by the N path, an output end of a previous inverter is connected to an input end of a next inverter, an input end of a first inverter is connected to the non-inverting port of the boost module, and an output end of a last inverter is connected to the grid electrode of the NMOS driving transistor.

12. (canceled)
